(19) United States
(12) Patent Application Publication
(10) Pub. No.: US 2024/0081000 A1
(43) Pub. Date: Mar. 7, 2024

(54) PEDAL ASSEMBLY HAVING A RELEASABLY COUPLED CONNECTOR ASSEMBLY AND METHODS OF FORMING THEREOF

(71) Applicant: KSR IP Holdings, LLC, Wilmington, DE (US)

(72) Inventor: Wjatscheslaw Kauz, Pattensen (DE)

(73) Assignee: KSR IP Holdings, LLC, Wilmington, DE (US)

(21) Appl. No.: 18/239,967

(22) Filed: Aug. 30, 2023

Related U.S. Application Data
(60) Provisional application No. 63/403,091, filed on Sep. 1, 2022.

(51) Int. Cl. H05K 5/00; G05G 1/38; G05G 1/44

(52) U.S. Cl. CPC H05K 5/0069; G05G 1/38; G05G 1/44; H05K 5/0034

(57) ABSTRACT

Embodiments herein are directed an assembly. The assembly includes a circuit board, a plurality of terminal pins, a first material layer, and a second material layer. The circuit board includes a plurality of electrical components. The plurality of terminal pins extend from the circuit board. The first material layer encases a portion of the circuit board and the plurality of electrical components. The second material layer encloses the first material layer and the circuit board. The second material layer defines a connector interface portion that includes a plurality of latch members extending therefrom. A material of the second material layer different from a material of the first material layer.

### CROSS-REFERENCE TO RELATED APPLICATIONS

This utility patent application claims priority benefit from U.S. Provisional Patent Application Ser. No. 63/403,091, filed Sep. 1, 2022, and entitled “Interface Housing Having Multi-Layers of Overmold Materials and Snap Features”, the entire contents of which is incorporated herein in its entirety.

### TECHNICAL FIELD

The present specification generally relates to a connector assembly, and more specifically to a connector assembly with overmold materials.

### BACKGROUND

Connectors are used in many applications to provide a direct link between a circuit board and a harness that ultimately transmits data between the circuit board and a controller. Protecting the connector and the circuit board has become increasing more important due to the positioning of the connectors and the circuit boards for environmental reasons, packaging reasons, and the like. As such, a need exists for an improved connector assemblies and circuit boards that are better protected.

### SUMMARY

In one embodiment, an assembly is provided. The assembly includes a circuit board, a plurality of terminal pins, a first material layer, and a second material layer. The circuit board includes a plurality of electrical components. The plurality of terminal pins extend from the circuit board. The first material layer encases a portion of the circuit board and the plurality of electrical components. The second material layer encloses the first material layer and the circuit board. The second material layer defines a connector interface portion that includes a plurality of latch members extending therefrom. A material of the second material layer different from a material of the first material layer.

In another embodiment, a pedal assembly is provided. The pedal assembly includes a housing, a pedal arm, and a connector assembly. The housing includes a plurality of tabs extending therefrom. The pedal arm is configured to move relative to the housing. The connector assembly is releasably coupled to the housing. The connector assembly includes a circuit board, a plurality of electrical components, a plurality of terminal pins, a first material layer, and a second material layer. The circuit board includes a first end, an opposite second end, and a surface extending between the first end and the second end. The plurality of electrical components are coupled to the surface adjacent to the first end. The plurality of terminal pins extend from the first end of the circuit board. The first material layer encases the first end, the plurality of electrical components, and a portion of the plurality of terminal pins. The second material layer encloses the first material layer and the circuit board. The second material layer defines a connector interface portion and a plurality of latch members. Each of the plurality of latch members include an opening that is configured to receive a respective tab from the plurality of tabs of the housing to releasably couple the connector assembly to the housing.

In another embodiment, an assembly is provided. The assembly includes a housing and a connector assembly. The housing has a plurality of tabs extending therefrom. The connector assembly is releasably coupled to the housing. The connector assembly includes a circuit board, a plurality of terminal pins, a first material layer, and a second material layer. The plurality of terminal pins extend from the circuit board. The first material layer encases a portion of the circuit board and a portion of the plurality of terminal pins. The second material layer encloses the first material layer and the circuit board. The second material layer defines a connector interface portion and a plurality of latch members. Each of the plurality of latch members include an opening that is configured to receive a respective tab from the plurality of tabs of the housing to releasably couple the connector assembly to the housing.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a perspective view of a pedal assembly in a home position that includes a releasably coupled connector assembly according to one or more embodiments shown and described herein;

FIG. 2 schematically depicts a perspective view of the pedal assembly of FIG. 1 in a fully depressed position according to one or more embodiments shown and described herein;

FIG. 3 schematically depicts a partial exploded view of the pedal assembly of FIG. 1 with the connector assembly separated from a housing according to one or more embodiments shown and described herein;

FIG. 4 schematically depicts an isolated perspective and exterior view of the connector assembly of the pedal assembly of FIG. 1 according to one or more embodiments shown and described herein;

FIG. 5 schematically depicts an isolated perspective and interior view of the connector assembly of the pedal assembly of FIG. 1 according to one or more embodiments shown and described herein;

FIG. 6 schematically depicts an isolated perspective and top view of the connector assembly of the pedal assembly of FIG. 1 according to one or more embodiments shown and described herein;

FIG. 7 schematically depicts an isolated partial exploded view taken from a top-down perspective of the connector assembly of the pedal assembly of FIG. 1 according to one or more embodiments shown and described herein;

FIG. 8 schematically depicts an isolated partial exploded view from a bottom-top perspective of the connector assembly of the pedal assembly of FIG. 1 according to one or more embodiments shown and described herein; and

FIG. 9 schematically depicts an illustrative flowchart for a method of forming the connector assembly of the pedal assembly of FIG. 1 according to one or more embodiments shown and described herein.

### DETAILED DESCRIPTION

Connectors are used in many applications to provide a direct link between a circuit board on a component and a harness separate from the component that ultimately transmits data between the circuit board and a controller. Conventional assemblies rely solely on a housing in which the circuit board is housed or embedded within to protect the circuit board. However, the housing cavities that receive the circuitry board do not independently protect the circuit board or the electrical components thereof. Further, upon a failure of any of the electrical components, in conventional assemblies, the entire assembly must be replaced. This is expensive and time consuming. Further, there is no versatility in the application of the connector assembly.

Embodiments described herein are directed to a assembly that includes a connector assembly that is releasably coupled to a housing. The connector assembly includes a circuit board with a plurality of electrical components and a plurality of terminal pins extending thereform. A first material layer is positioned to encase at least a portion of the circuit board, the plurality of electrical components and at least a portion of the plurality of terminal pins. As such, the first material layer seals and protects the various components of the circuit board. A second material layer encloses and/or encases the first material layer and the circuit board and encloses portions of the plurality of terminal pins while encapsulates other portions of the plurality of terminal pins, thereby forming a connector interface that communicatively couples the connector assembly to a vehicle side connector. A plurality of latch members are formed by the second material layer and are configured to receive a corresponding tab on the housing such that the connector assembly may be releasably coupled to the housing.

Various embodiments of the connector assembly and methods for assembly are described in detail herein.

As used herein, the term “communicatively couple” means that coupled components are capable of exchanging data signals and/or electric signals with one another such as, for example, electrical signals via conductive medium, electromagnetic signals via air, optical signals via optical waveguides electrical energy via conductive medium or a non-conductive medium, data signals wirelessly and/or via conductive medium or a non-conductive medium and the like.

As used herein, the term “encase” or “enclose”, means to enclose or cover with a direct contact and the term “encapsulate” means to surround without a direct contact.

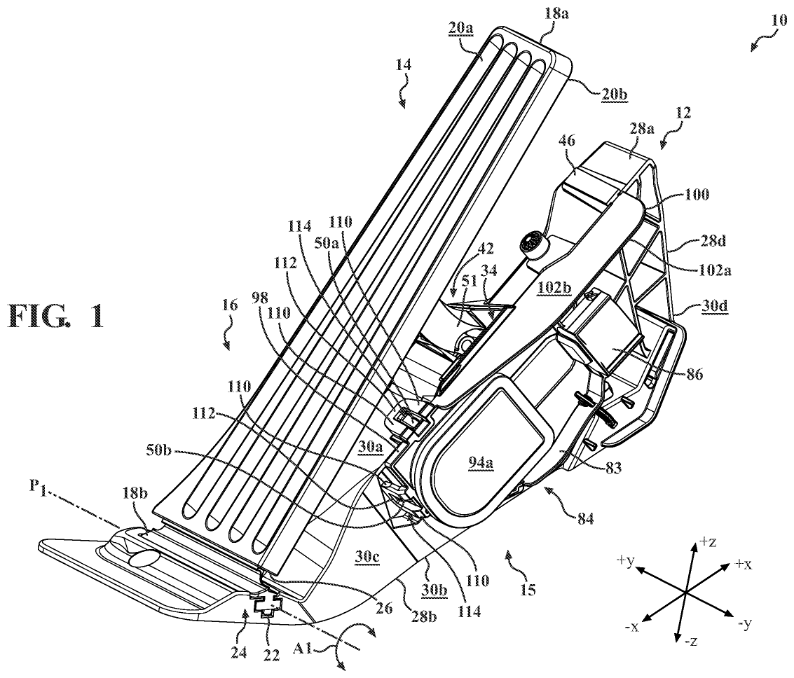

Further, as used herein, the term “longitudinal direction” refers to the forward-rearward direction of the pedal assembly (i.e., in the +/−X-direction depicted in the coordinate axes of FIG. 1). The term “lateral direction” refers to the cross-electrical device direction (i.e., in the +/−Y-direction depicted in the coordinate axes of FIG. 1), and is transverse to the longitudinal direction. The term “vertical direction” or “below” or “above” refer to the upward-downward direction of the pedal assembly (i.e., in the +/−vehicle Z-direction depicted in the coordinate axes of FIG. 1).

Referring now to FIGS. 1-3, an example pedal assembly 10 is schematically depicted. The example pedal assembly 10 includes a housing 12, a pedal arm assembly 14, and a connector assembly 15. The pedal arm assembly 14 includes a pedal arm 16 coupled to a link member 51 that is positioned to be depressed into a cavity 34 of the housing 12. Within the cavity may be other pedal arm assembly components such as a spring carrier assembly 58, a lever arm 66, and the like, to permit the pedal arm 16 to move or pivot relative to the housing 12 while moving the link member 51 and the other components. The pedal arm 16 includes a pedal pad end 18a and a pivot end 18b. Further, the pedal arm 16 includes an exterior surface 20a and an opposite interior surface 20b spaced apart from the exterior surface 20a to define a thickness of the pedal arm 16. In some embodiments, the pedal arm 16 is generally planar shaped. In other embodiments, the pedal arm 16 may be differently shaped such as curvilinear, arcuate, and/or the like. The pivot end 18b is pivotally coupled to the housing 12 about a pivot axis P1 to move or pivot about the pivot axis P1, illustrated by the arrow A1 in FIG. 1. For example, in the depicted embodiments, the pivot end 18b slidably engages with a receiving slot 22 of the housing 12.

In some embodiments, the pivot end 18b may be a plate 24 that is coupled to a distal end 26 of the pedal arm 16 via a fastener such as a screw, rivet, bolt and nut, press fit, epoxy, adhesive, weld, and/or the like. As such, the pivot end 18b may act as a living hinge to allow the pedal arm 16 to move between a home position, (e.g., no load), to a fully depressed position (e.g., full load), and a plurality of depressed positions therebetween about the pivot axis P1 in the directions illustrated by arrow A1.

In some embodiments, the pivot end 18b may generally be a T-shape as depicted and the receiving slot 22 may have a corresponding shape to receive the pivot end 18b and allow the pivot end 18b to move or pivot about the pivot axis P1 within the receiving slot 22. This is non-limiting and the pivot end 18b may be any shape, such as rectangular, square, hexagonal, octagonal, cylinder and the like. Further, the receiving slot 22 of the housing 12 may be any shape to correspond to the shape of the pivot end 18b to allow the pivot end 18b to pivot or move about the pivot axis P1, illustrated by the arrow A1 in FIG. 1. Further, in other embodiments, the pivot end 18b may be coupled to the housing 12 via a fastener, such as a screw, rivet, pin, dowel, bolt and nut, and/or the like. Further, in other embodiments, the distal end 26 may be directly coupled to the housing 12 via a fastener, such as a screw, rivet, pin, dowel, bolt and nut, and/or the like, to act as the pivot end and thus without the need for the plate 24.

The exterior surface 20a of the pedal arm 16 may be a pedal pad or may receive a pedal pad that a foot of a user would depress against to brake, accelerate, and/or activate a clutch control. The interior surface 20b includes an attachment portion that receives and couples the link member 51 to the pedal arm 16. The attachment portion may be any mechanical device capable of coupling the link member 51 to the pedal arm 16, such as, without limitation, a pair of spaced apart flanges that may include indentions and/or other mechanical devices and/or components to couple or attach the pedal arm 16 to a link member 51.

The housing 12 includes an upper wall 28a, an opposite lower wall 28b, an end wall 28d, and a sidewall 28c extending therebetween. Each of the upper wall 28a, the lower wall 28b, and the sidewall 28c have an outer surface 30a, 30b, 30c, 30d, respectively and an opposite inner surface 32a, 32b, 32c, 32d. When in the coupled or attached position, as best illustrated in FIG. 1 the connector assembly 15 forms the opposite sidewall (e.g., opposite of the sidewall 28c) to enclose the cavity 34 when installed, as discussed in greater detail herein.

A friction generating member 38 extends from the inner surface 32c of the sidewall 28c. In some embodiments, the friction generating member 38 is integrally formed with the inner surface 32c of the sidewall 28c as a one piece monolithic structure with the sidewall 28c. In other embodiments, the friction generating member 38 may be coupled to the inner surface 32c of the sidewall 28c via a fastener, such as, without limitation, screws, rivets, bolt and nuts, adhesive, epoxy, weld, and/or the like.

In some embodiments, the friction generating member 38 may include an interior surface 40a and an opposite exterior surface 40b. In some embodiments, the interior surface 40a may have a smooth contour. In other embodiments, the interior surface 40a may include a liner or other material to form the smooth contour. The friction generating member 38 and/or the interior surface 40a thereof may be arcuate in shape. For example, the friction generating member 38 and/or the interior surface 40a thereof may be semi-circular, semi-annular, and the like. In other embodiments, the friction generating member 38 and/or the interior surface 40a thereof may be other shapes such as circular, hexagonal, octagonal, and/or the like. As such, in other embodiments, the friction generating member 38 and/or the interior surface 40a thereof may not be arcuate, or may include arcuate portions. Further, the friction generating member 38 may extend from the inner surface 32a and/or the inner surface 32c and may define a portion of the cavity 34.

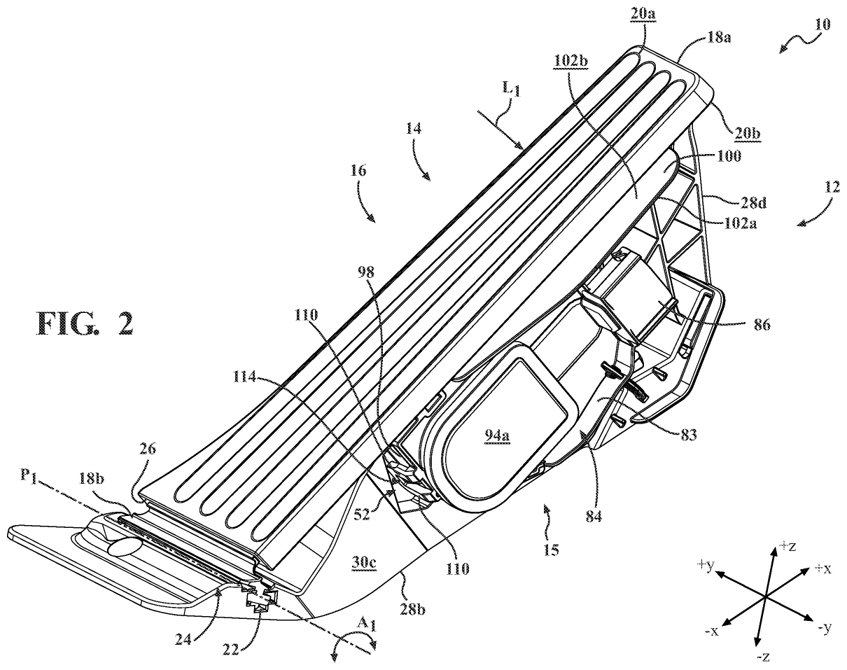

Still referring to FIGS. 1-2, the upper wall 28a further includes an opening 42 and a receiving channel 44 that are each positioned within the outer surface 30a and the receiving channel 44 is configured to receive a damper 46 or bumper stop. The damper 46 or bumper stop may be an elastic material, rubber, and the like, and configured to cushion and provide an end of travel of the pedal arm 16 when in the fully depressed position. Further, the damper 46 or bumper stop may be slidably engaged within the receiving channel 44 to lock or retain the damper 46 or stop within the receiving channel 44. The opening 42 provides access to the cavity 34 of the housing 12. Further, in some embodiments, the inner surface 32a of the upper wall 28a may include a receiving channel 64 for receiving a damper 65 or bumper stop. The damper 65 or bumper stop may be an elastic material, rubber, and the like, and may be configured to cushion the lever arm 66 when the pedal arm 16 is in the home position, as best illustrated in FIG. 2. That is, the damper 65 may be configured to engage or abut with a surface of the lever arm 66 when the pedal arm is in the home position to reduce noise, vibration, and/or harshness. Further, the damper 65 or bumper stop may be slidably engaged within the receiving channel 64 to lock or retain the damper 65 or stop within the receiving channel 64.

The cavity 34 may be defined by a floor surface 54a, a terminating cavity wall surface 54b of a terminating cavity wall 53, and the friction generating member 38 such that the friction generating member 38 extends between and from the floor surface 54a and/or the inner surface 32b of the upper wall 28a on one end of the cavity 34 and the terminating cavity wall surface 54b is positioned at the opposite end with the floor surface 54a therebetween.

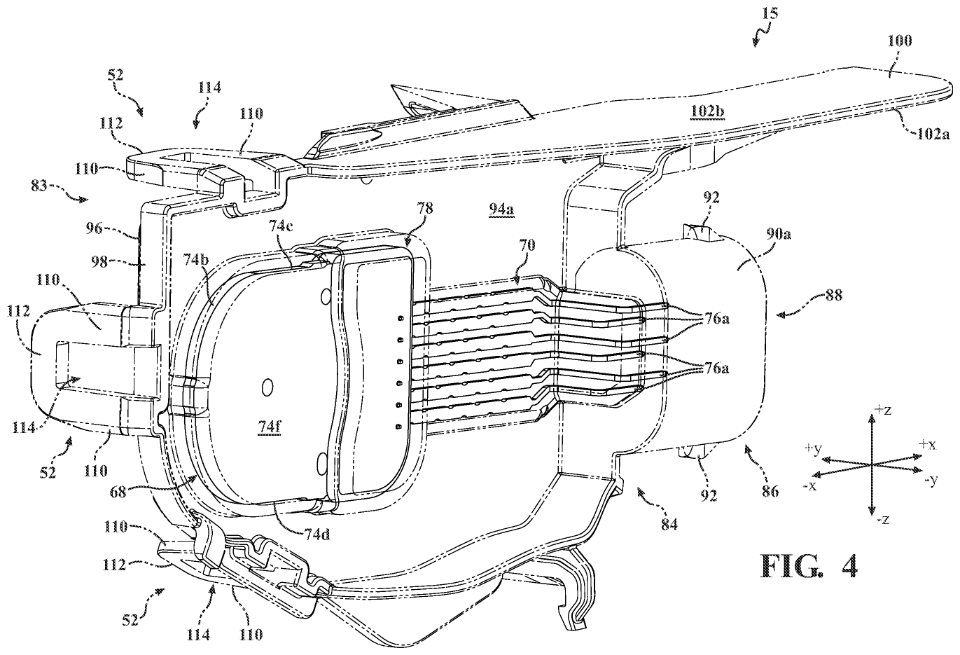

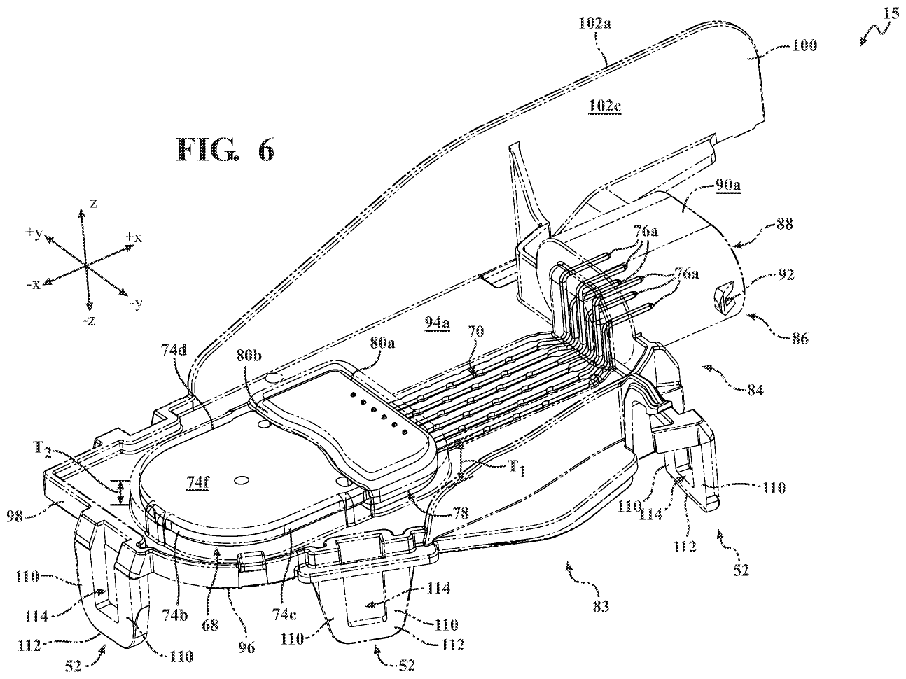

The housing 12 include a plurality of tabs 48. The plurality of tabs 48 are positioned to receive a portion of the connector assembly 15 to releasable couple the connector assembly 15 to cover or act as a sidewall opposite of the sidewall 28c to enclose the cavity 34. Each of the tabs of the plurality of tabs 48 may be protrusions that include an angled portion and a planar portion to lock or engage with a corresponding latch feature of a plurality of latch members 52 (FIGS. 4-8) of the connector assembly 15, as discussed in greater detail herein.

In the depicted embodiment, and without limitation, one tab 50a of the plurality of tabs 48 may extend from the outer surface 30a of the upper wall 28a. Further, a second tab 50b of the plurality of tabs 48 may be positioned to extend from the exterior surface 40b of the friction generating member 38. A third tab 50c may be positioned within a recess 56 positioned within the lower wall 28b of the housing 12. A fourth tab 50d may be positioned between the terminating cavity wall surface 54b and the end wall 28d and may be positioned to extend from a surface 62 of at least one reinforcement rib 60 positioned to extend between the upper wall 28a and the lower wall 28b and extends between the end wall 28d and the terminating cavity wall 53. A fifth tab 50e may be positioned to extend from the inner surface 32a of the upper wall 28a between the terminating cavity wall 53 and the at least one reinforcement rib 60.

In some embodiments, the housing 12 may be a molded plastic. For example, the housing 12 may be formed with various materials such as acrylonitrile butadiene styrene (ABS), polyethylene (PE), polypropylene (PP), polycarbonate (PC), nylon, polycarbonate/acrylonitrile butadiene styrene, polyurethane, polymethyl methacrylate, high density polyethylene, low density polyethylene, polystyrene, PEEK, POM (Acetal/Delrin), polyethylene terephthalate, thermoplastic elastomer, polyetherimide, theremoplastic vulcanizate, polysulfone, combinations thereof, and/or the like. Additionally, additives may be added such as UV absorbers, flame-retardants, colorants, glass fibers, plasticizers and/or the like.

In other embodiments, the housing 12 may be additively manufactured. Additively manufactured refers generally to manufacturing processes wherein successive layers of material(s) are provided on each other to “build-up,” layer-by-layer, a three-dimensional component. The successive layers generally fuse together to form a monolithic component which may have a variety of integral sub-components. Although additive manufacturing technology is described herein as enabling fabrication of complex objects by building objects point-by-point, layer-by-layer, typically in a vertical direction, other methods of fabrication are possible and within the scope of the present subject matter. For example, although the discussion herein refers to the addition of material to form successive layers, one skilled in the art will appreciate that the methods and structures disclosed herein may be practiced with any additive manufacturing technique or manufacturing technology. For example, embodiments of the present invention may use layer-additive processes, layer-subtractive processes, or hybrid processes.

Suitable additive manufacturing techniques in accordance with the present disclosure include, for example, Fused Deposition Modeling (FDM), Selective Laser Sintering (SLS), 3D printing such as by inkjets and laserjets, Sterolithography (SLA), Direct Selective Laser Sintering (DSLS), Electron Beam Sintering (EBS), Electron Beam Melting (EBM), Laser Engineered Net Shaping (LENS), Laser Net Shape Manufacturing (LNSM), Direct Metal Deposition (DMD), Digital Light Processing (DLP), Direct Selective Laser Melting (DSLM), Selective Laser Melting (SLM), Direct Metal Laser Melting (DMLM), and other known processes.

The housing 12 may be floor mounted. That is, in some embodiments, the housing 12 may be coupled or mounted to be positioned within or extending from a floor surface of a vehicle. As such, the cavity 34 of the housing accommodates the pedal arm 16 at full depression to allow the pedal arm 16 to fully travel between the home position, the fully depressed position, and a plurality of positions there between.

Now referring to FIGS. 1-7, the connector assembly 15 includes a circuit board 68, a plurality of terminal pins 70 extending therefrom, and a plurality of electrical components 72 positioned thereon. The circuit board 68 includes a first end 74a, an opposite second end 74b, a pair of edges 74c, 74d extending between the first end 74a and the second end 74b, and includes an exterior surface 74e and an opposite interior surface 74f. The exterior surface 74e and the interior surface 74f extend between the first end 74a and the second end 74b and between the pair of edges 74c, 74d. The circuit board 68 may be a printed circuit board, a flexible circuit board, or other kind of circuit boards known to those in the art.

The second end 74b of the circuit board 68 may generally be a curvilinear shape whereas the first end 74a may generally planar or be linear in shape. The plurality of terminal pins 70 may be communicatively coupled or otherwise attached to the first end 74a and communicatively coupled to the electrical components 72 and extend outwardly from the first end 74a. Each terminal pin of the plurality of terminal pins 70 has a terminating end 76a and a coupled end 76b. The coupled end 76b may be communicatively coupled to the first end 74a of the circuit board 68. In some embodiments, each of the plurality of terminal pins 70 may be spring loaded.

In some embodiments, the plurality of electrical components 72 may extend from the exterior surface 74e near or adjacent to, or closer to, the first end 74a than compared to the second end 74b. In other embodiments, the plurality of electrical components 72 may extend from the interior surface 74f and/or some may extend from the interior surface 74f while others extends from the exterior surface 74e. As such, the plurality of electrical components 72 may extend between and through the exterior surface 74e and/or the interior surface 74f of the circuit board 68. The plurality of electrical components 72 may include components such as semiconductors, application-specific integrated circuit, resistors, transistors, capacitors, inductors, oscillators, Hall Effect chips, wake-up switches, and the like.

A first material layer 78 may coat and/or encase the first end 74a of the circuit board 68 along with portions of the exterior surface 74e and the interior surface 74f of the circuit board 68, the plurality of electrical components 72 and the coupled end 76b of the plurality of terminal pins 70. The first material layer 78 may include a first terminating portion 80a and an opposite second terminating portion 80b. The second terminating portion 80b terminates before encasing the second end 74b of the circuit board 68. In some embodiments, the second terminating portion 80b is curvilinear in shape. In other embodiments, the first terminating portion 80a is linear or other shapes.

In some embodiments, a receiving slot 82 may extend from the first terminating portion 80a. In some embodiments, the receiving slot 82 may be an elongated slot configured to receive portions of each of the plurality of terminal pins 70. In other embodiments, the receiving slot 82 may include a plurality of perforations to allow portions of each one of the plurality of terminal pins 70 to extend therethrough. In some embodiments, the receiving slot 82 maybe triangular in shape. In other embodiments, the receiving slot 82 may be rectangular, circular, and/or the like. As such, the first material layer 78 may encase other portions of the plurality of terminal pins 70 other than the coupled end 76b.

It should be understood that the first material layer 78 may seal and protect the plurality of electrical components 72, portions of the circuit board 68, and portions of the plurality of terminal pins 70 that are beneath, coated by, or encased by the first material layer 78.

The first material layer 78 may be an overmold material such as a low pressure epoxy overmold. For example, a material of the first material layer 78 may be various materials such as acrylonitrile butadiene styrene (ABS), polyethylene, polypropylene, polycarbonate, polyimide thermoplastic—known as nylon—and variations of nylon including PA6 and PA66, polyphthalamide, polycarbonate/acrylonitrile butadiene styrene, polyurethane polymethyl methacrylate, high density polyethylene, low density polyethylene, polystyrene, polyether ether ketone, polyoxymethylene (Acetal/Delrin), polyethylene terephthalate, thermoplastic elastomer, polyetherimide, theremoplastic vulcanizate, polysulfone, and/or the like, and combinations thereof. Additionally, additive may be added such as ultraviolet (UV) absorbers, flame-retardants, colorants, glass fibers, plasticizers, carbon fiber, aramid fiber, glass bead, PTFE, PFPE, TALC, Molybdenum Disulfide, graphite, and/or the like.

In some embodiments, the first material layer 78 may be formed through injection molding. The overmold may be one continuous piece of construction, but it is to be understood that the overmold may have different constructions. In some embodiments, the overmold may be coupled or bonded together using any suitable method or manufacture such as snap fit arrangement, friction fit arrangement, press fit arrangement, mechanical clamping, and the like.

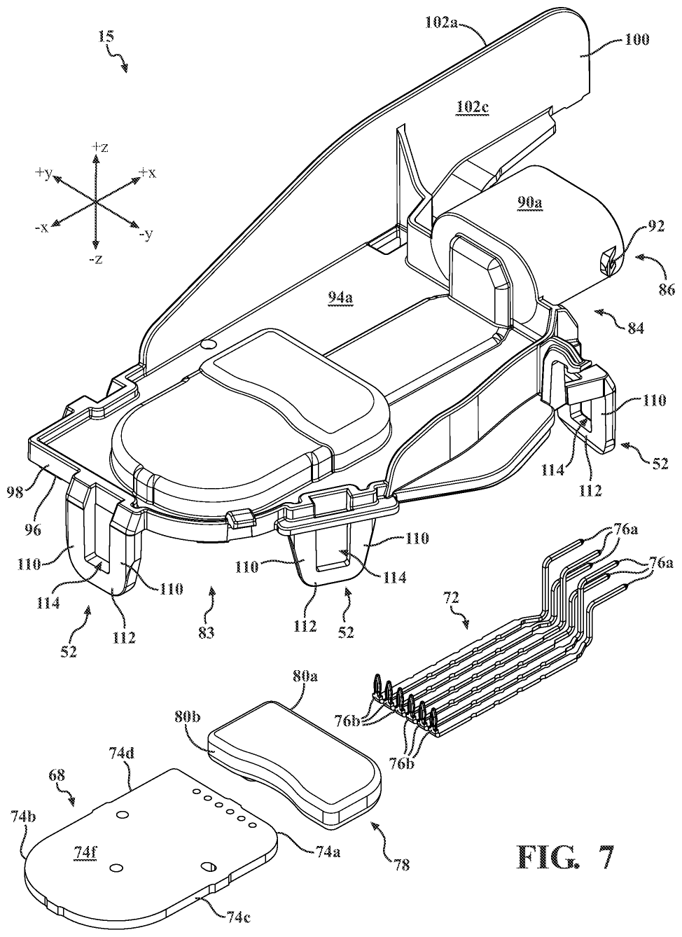

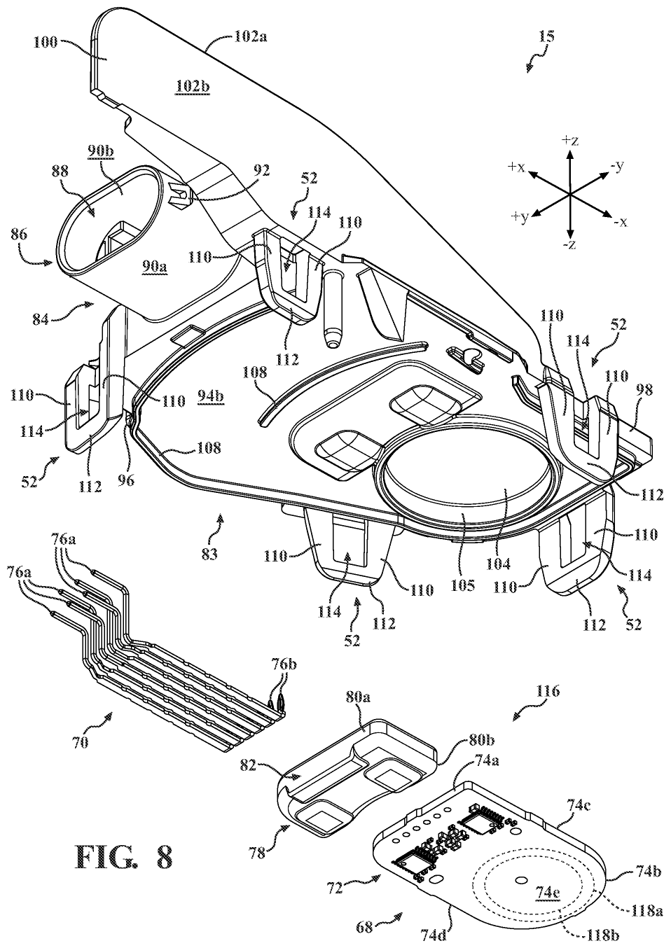

Still referring to FIGS. 1-7, a second material layer 83 may be used to form and/or define a connector interface portion 84. The second material layer 83 circumferentially coats and/or encases the entire first material layer 78 along with the second end 74b of the circuit board 68. That is, the second material layer 83 encases or covers the first material layer 78, covers the entire circuit board 68 including both the first end 74a and the second end 74b, the edges 74c, 74d, the exterior surface 74e, and interior surface 74f of the circuit board 68, the plurality of electrical components 72 and the coupled end 76b of the plurality of terminal pins 70. As such, it should be understood that the various exploded views in FIGS. 7-8 merely illustrate the second material layer 83 as preformed or separated for ease of illustrating the first material layer 78 and the circuit board 68 are encased by the second material layer 83. As such, the second material layer 83 may be a continuous coating to encase the first material layer 78, the circuit board 68 and the electrical components 72. As such, the connector assembly 15 includes the connector interface portion 84 formed from the second material layer 83, the first material layer 78, the circuit board 68, the plurality of terminal pins 70, and the plurality of electrical components 72.

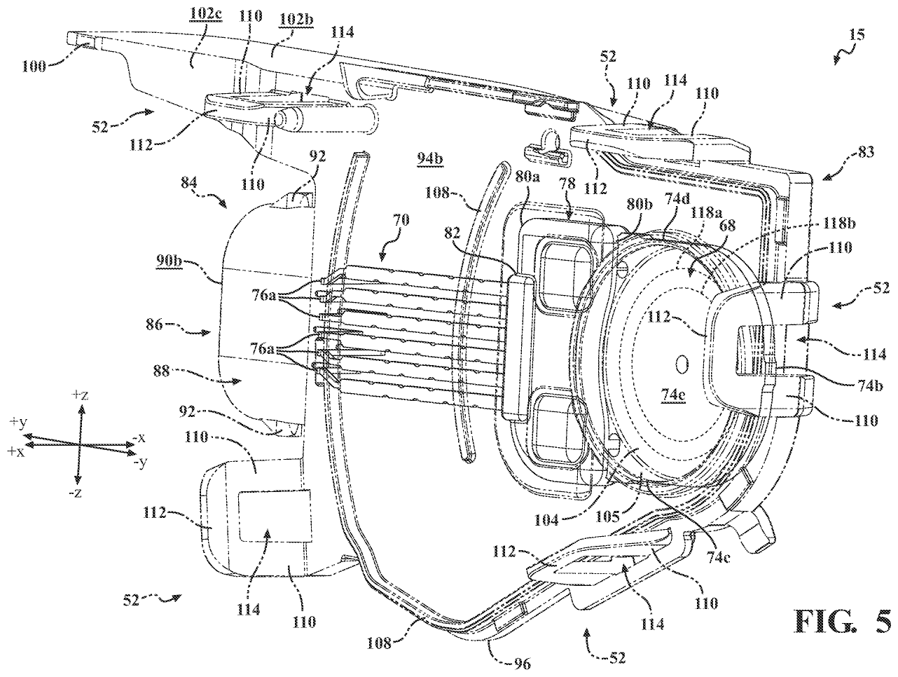

The connector interface portion 84 may include an exterior surface 94a and an opposite interior surface 94b that is spaced apart from the exterior surface 94a to form a thickness. Portions of the second material layer 83 may be thicker than other portions or extend a different distance away from the circuit board 68 because of the thickness of the first material layer 78. That is, the second material layer 83 may extend or be thicker in areas where there is the first material layer 78, as best illustrated in FIG. 5 where the second material layer 83 extends in the vertical direction (i.e., in the +/−X direction) covering the first material layer 78 illustrated by arrow T1 a greater distance or thickness from the exterior surface 94a than where the second material layer 83 extends in the vertical direction (i.e., in the +/−X direction) from the exterior surface 94a covering only the second end 74b of the circuit board 68 without the first material layer 78 illustrated by arrow T2.

Additionally, the connector interface portion 84 may be molded such that the second material layer 83 forms or defines a connector 86 that has an cavity 88 and encapsulates the terminating end 76a of each of the plurality of terminal pins 70 without enclosing the terminating end 76a of each of the plurality of terminal pins 70 such that a vehicle side connector may have access to at least the terminating end 76a of each of the plurality of terminal pins 70 via the cavity 88. That is, the cavity 88 circumferentially surrounds the terminating end 76a of each of the plurality of terminal pins 70 without encasing, but encapsulating the terminating end 76a of each of the plurality of terminal pins 70 such that access is provided to the plurality of the terminating end 76a of each of the plurality of terminal pins 70 within the cavity 88. As such, the second material layer 83 forms and/or defines the connector 86 that includes an outer surface 90a and an opposite inner surface 90b and such that the inner surface 90b is spaced apart from each of the plurality of terminal pins 70 to form and/or define the cavity 88.

A pair of protrusions 92 extend from the outer surface 90a of the connector 86. Each of the pair of protrusions 92 may receive a receiving aperture of a vehicle-side connector assembly to releasably lock, couple, and/or engage the vehicle-side connector assembly to the connector 86 via the pair of protrusions 92. As such, while the pair of protrusions 92 are generally illustrated as a triangular shape, this is non-limiting and each of the pair of protrusions 92 may be any shape including square, circular, rectangular, hexagonal, regular, irregular, and/or the like. Further, the connector 86 may include various mating features such as apertures, indentions, protrusions, recesses, and the like, to provide proper alignment and a secured coupling between the connector 86 formed and/or defined by the second material layer 83 and the vehicle side connector or interface.

Further, the connector interface portion 84 includes a peripheral edge 96 extending around a perimeter of the connector interface portion 84. In some embodiments, a continuous wall 98 may be positioned to extend from the exterior surface 94a of the connector interface portion 84 in the lateral direction (i.e., in the +/−Y direction). In some embodiments, the continuous wall 98 may be positioned to define the peripheral edge 96 and/or extending from the peripheral edge 96. In some embodiments, an elongated portion 100 of the continuous wall 98 may extend from the exterior surface 94a of the connector interface portion 84 in the lateral direction (i.e., in the +/−Y direction) a distance greater than the other portions of the continuous wall 98. The elongated portion 100 of the continuous wall 98 includes a terminating edge 102a, a pedal side surface 102b and an opposite connector side surface 102c that form a planar surface, as depicted in the illustrated embodiment. This is non-limiting, and the pedal side surface 102b and/or the connector side surface 102c may be arcuate, wavy, honeycombed, perforated, and the like. The pedal side surface 102b faces the interior surface 20b of the pedal arm 16 and the connector side surface 102c faces the connector 86. As such, in the coupled position, the pedal side surface 102b may abut or be adjacent to the interior surface 20b of the pedal arm 16 when the pedal arm 16 is in the fully depressed position from a load L1 and the connector side surface 102c of the elongated portion 100 provides a cover or shield to the connector 86, as best illustrated in FIG. 2.

The interior surface 94b of the connector interface portion 84 may further include a recess portion 104. Further, in some embodiments, a perimeter wall 105 extends from the interior surface 94b in the lateral direction (i.e., in the +/−Y direction) to circumferentially surround the recess portion 104. In the illustrated embodiments, the recess portion 104 and the perimeter wall 105 are illustrated as circular to correspond to the size and geometry of the hub portion 71 of the lever arm 66 where a coupler 99 is positioned therein and/or thereon. As such, the recess portion 104 and the perimeter wall 105 permit the coupler 99 to extend into the recess portion 104 thereby minimizing an airgap between the circuit board 68 enclosed by the second material layer 83 and the coupler 99. As such, in some embodiments, the coupler 99, the transmitting coil 118a and the at least one receiver coil 118b are positioned to be concentrically aligned with the recess portion 104. In other embodiments, recess portion 104, the coupler 99, the transmitting coil 118a and the at least one receiver coil 118b are coaxially aligned. Such an arrangement may permit a sensor assembly 116 to better detect movement of the pedal arm 16 via inductive sensing principles and/or Hall Effect sensing principles, as discussed in greater detail herein.

The connector interface portion 84 may further include at least one rib 108 or protrusion that extends from the interior surface 94b in the lateral direction (i.e., in the +/−Y direction). The at least one rib 108 may be positioned to follow portions of the peripheral edge 96. Further, the at least one rib 108 may include several ribs that are disjoined or not continuous with one another. As such, the at least one rib 108 may be configured to provide additional support, rigidly, and/or the like.

The connector interface portion 84 may further include the plurality of latch members 52. In some embodiments, each, some, and/or all of the plurality of latch members 52 extend from the peripheral edge 96 in a direction from the exterior surface 94a of the connector interface portion 84 towards and beyond the interior surface 94b of the connector interface portion 84 in the lateral direction (i.e., in the +/−Y direction). In some embodiments, each and/or some of the plurality of latch members 52 may be a resilient member that is able to move or bend at or near the peripheral edge 96 to form a limited movement living hinge. In other embodiments, each and/or some of the plurality of latch members 52 may be rigid. In the depicted embodiment, each of the plurality of latch members 52 include a pair of legs 110 connected to one another by a base member 112 to generally form a U-shape latch with an opening 114 and formed as a single monolithic structure (e.g., a single component). In some embodiments, each of the pair of legs 110 are symmetrical. In other embodiments, the pair of legs may be asymmetrical with respect to one another. The pair of legs 110 may extend from the peripheral edge 96. As such, portions of the pair of legs 110 may form a partial movement living hinge at or near the peripheral edge 96 such that the plurality of latch members 52 act as resilient members.

Each of the openings 114 of the plurality of latch members 52 are configured to receive a respective tab from the plurality of tabs 48. As such, the plurality of latch members 52 may be spaced apart and may extend from various portions of the peripheral edge 96, from the interior surface 94b, and/or from the exterior surface 94a such that the opening 114 is aligned to receive the corresponding tab from the plurality of tabs 48 of the housing 12. As such, the plurality of latch members 52 and the plurality of tabs 48 of the housing 12 together permit the connector assembly 15 to be releasably coupled to the housing 12.

It should be understood that many different structures such as different latches, protrusions, resilient members, and openings may be used to couple the connector assembly 15 of to the housing 12. As such, the connector assembly 15 may be releasably coupled to the housing 12 via a snap fit, friction fit, press fit or the like. Further, the connector assembly 15 may be removably coupled to the housing 12 for disassembling and reassembly of the connector assembly 15. As such, the elongated portion 100 and other portions of the continuous wall 98 may be used to provide a handhold for grip on the connector assembly 15 to remove or insert the connector assembly 15 to and from the housing 12.

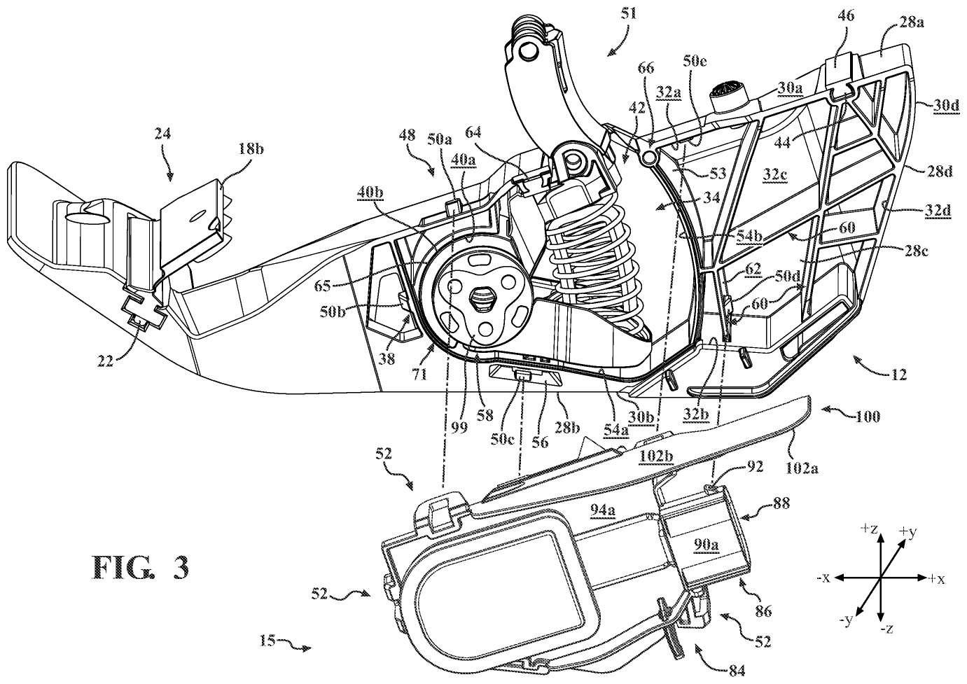

Referring back to FIGS. 3 and 8, the sensor assembly 116 includes the coupler 99, the circuit board 68, and the plurality of terminal pins 70. The circuit board 68 may further include at least one transmitter coil 118a and at least one receiver coil 118b that is circumferentially surrounded by the at least one transmitter coil 118a. The at least one transmitter coil 118a and the at least one receiver coil 118b may be positioned on the circuit board 68 to be positioned in the recess portion 104. As such, the coupler 99 may be positioned adjacent to the at least one receiver coil 118b and/or at least one transmitter coil 118a. The coupler 99 may rotate, pivot, or move upon movement of the hub portion 71 of the lever arm 66 when the load applied onto the pedal arm 16 moves the link member 51, which in turn moves the lever arm 66, thereby rotating the hub portion 71. The at least one receiver coil 118b and the at least one transmitter coil 118a detect the movements of the coupler 99 via inductive sensing principles and that data is transmitted to an ECU and/or powertrain controller communicatively coupled to the sensor assembly 116 via the connector 86. For example, the at least one receiver coil 118b is configured and positioned to sense a change in eddy currents caused from the movement of the coupler 99 such that the movement of the coupler 99 is detected by the sensor assembly 116.

It should be understood that the at least one receiver coil 118b and the at least one transmitter coil 118a may be replaced with, or work in conjunction with, a Hall Effect sensing chip mounted to the circuit board 68 and the coupler 99 may be replaced with, or work in conjunction with a magnet as a target coupled to and/or within the hub portion 71 such that Hall Effect sensing is also possible.

It should now be understood that the connector interface portion 84 including the connector 86 and the plurality of latch members 52 are integrally formed as a single monolithic structure formed from the second material layer 83.

In some embodiments, the connector interface portion 84 may be additively manufactured. Additively manufactured refers generally to manufacturing processes wherein successive layers of material(s) are provided on each other to “build-up,” layer-by-layer, a three-dimensional component. The successive layers generally fuse together to form a monolithic component which may have a variety of integral sub-components. Although additive manufacturing technology is described herein as enabling fabrication of complex objects by building objects point-by-point, layer-by-layer, typically in a vertical direction, other methods of fabrication are possible and within the scope of the present subject matter. For example, although the discussion herein refers to the addition of material to form successive layers, one skilled in the art will appreciate that the methods and structures disclosed herein may be practiced with any additive manufacturing technique or manufacturing technology. For example, embodiments of the present invention may use layer-additive processes, layer-subtractive processes, or hybrid processes.

Suitable additive manufacturing techniques in accordance with the present disclosure include, for example, Fused Deposition Modeling (FDM), Selective Laser Sintering (SLS), 3D printing such as by inkjets and laserjets, Sterolithography (SLA), Direct Selective Laser Sintering (DSLS), Electron Beam Sintering (EBS), Electron Beam Melting (EBM), Laser Engineered Net Shaping (LENS), Laser Net Shape Manufacturing (LNSM), Direct Metal Deposition (DMD), Digital Light Processing (DLP), Direct Selective Laser Melting (DSLM), Selective Laser Melting (SLM), Direct Metal Laser Melting (DMLM), and other known processes.

In other embodiments, the second material layer 83 may form and/or define the connector interface portion 84 through injection molding. The overmold may be one continuous piece of construction, but it is to be understood that the overmold may have different constructions. In some embodiment the overmold may be coupled or bonded together using any suitable method or manufacture such as snap fit, friction fit, press fit, and mechanical clamping.

In some embodiments, the second material layer 83 may be a high-pressure mold and is formed of a Polybutylene Terephthalate material. In other embodiments, the second material layer 83 may be formed with various materials such as acrylonitrile butadiene styrene, polyethylene, polypropylene, polycarbonate, polyimide thermoplastic—known as nylon—and variations of nylon including PA6 and PA66, Polyphthalamide, polycarbonate/acrylonitrile butadiene styrene, polyurethane polymethyl methacrylate, high density polyethylene, low density polyethylene, polystyrene, polyether ether ketone, polyoxymethylene(Acetal/Delrin), polyethylene terephthalate, thermoplastic elastomer, polyetherimide, theremoplastic vulcanizate, polysulfone, and/or the like, and combinations thereof. Additionally, additives may be added such as ultraviolet (UV) absorbers, flame-retardants, colorants, glass fibers, plasticizers, carbon fiber, aramid fiber, glass bead, PTFE, PFPE, TALC, Molybdenum Disulfide, graphite, and/or the like. As such, the material of the second material layer 83 is different from the material of the first material layer 78 and may be formed using different injection techniques due to the second material layer 83 using high-pressure mold in some embodiments. In other embodiments, the second material layer 83 is not a high pressure mold but is an overmold formed from a polyimide thermoplastic. As such, and without limitation, in this embodiment, the second material layer 83 may also be formed with various other materials such as acrylonitrile butadiene styrene, polyethylene, polypropylene, polycarbonate, and variations of nylon including PA6 and PA66, Polyphthalamide, polycarbonate/acrylonitrile butadiene styrene, polyurethane polymethyl methacrylate, high density polyethylene, low density polyethylene, polystyrene, polyether ether ketone, polyoxymethylene(Acetal/Delrin), polyethylene terephthalate, thermoplastic elastomer, polyetherimide, theremoplastic vulcanizate, polysulfone, and/or the like, and combinations thereof. Additionally, additives may be added such as ultraviolet (UV) absorbers, flame-retardants, colorants, glass fibers, plasticizers, carbon fiber, aramid fiber, glass bead, PTFE, PFPE, TALC, Molybdenum Disulfide, graphite, and/or the like.

It should be understood that each material layer (e.g., the first material layer 78 and the second material layer 83) may be formed and/or defined with a different shape, from a different type of material, formed differently (e.g., low pressure, high pressure, and/or the like) and serve a different purpose. Further, only portions of each layer may overlap. For example, only a portion of the circuit board 68 is enclosed by the first material layer 78. The second material layer 83 encases the first material layer 78 and the circuit board 68, but only encapsulates a portion of the plurality of terminal pins 70 while encasing other portions of the plurality of terminal pins 70. The cavity 88 is provided for portions of the plurality of terminal pins 70 to extend within and that allows for access to the plurality of terminal pins 70 via a vehicle side connector to communicatively couple the circuit board 68 to a vehicle side controller, such as an electronic control unit with a processing device. As such, certain data gathered and/or provided to/by the circuit board 68, the sensor assembly 116, and/or the plurality of electrical components 72 positioned thereon may be communicated through the plurality of terminal pins 70 to the electronic control unit of the vehicle. For example, the certain data gathered and/or provided to/by the circuit board 68, the sensor assembly 116, and/or the plurality of electrical components 72 may be data related to movement of the pedal arm 16 and/or the coupler 99 and/or other or additional target(s) that moves either linearly or angularly indicative of movement of the pedal arm 16, which is dependent on a pressure or force applied to the exterior surface 20a of the pedal arm 16 by the user discussed as the load L1.

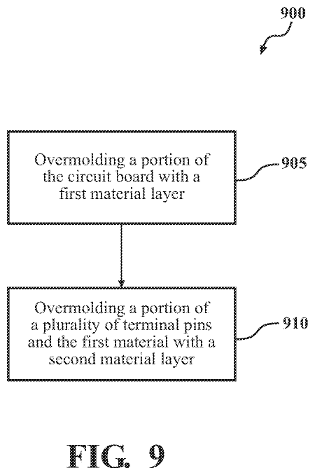

Still referring to FIGS. 1-8 and now referring now to FIG. 9, which is a flow diagram that graphically depicts an illustrative method 900 for forming the connector assembly 15. Although the steps associated with the blocks of FIG. 9 will be described as being separate tasks, in other embodiments, the blocks may be combined or omitted. Further, while the steps associated with the blocks of FIG. 9 will described as being performed in a particular order, in other embodiments, the steps may be performed in a different order.

At block 905, a portion of the circuit board 68 that includes the plurality of electrical components 72 and the coupled end 76b of the plurality of terminal pins 70 are overmolded with the first material layer 78 to encase the first end 74a of the circuit board 68, the plurality of electrical components 72 and the coupled end 76b of the plurality of terminal pins 70. The first material layer 78 may be a low-pressure epoxy. In some embodiments, the first material layer 78 may circumferentially encase the coupled end 76b of the plurality of terminal pins 70 and other portions of the plurality of terminal pins 70. For example, the first material layer 78 may encase the plurality of terminal pins 70 anywhere between the coupled end 76b and the terminating end 76a.

At block 910, the first material layer 78, the circuit board 68, and a portion of the plurality of terminal pins 70 that extend outwardly from the first end 74a of the circuit board 68 are overmolded with the second material layer 83 to encase each of the first material layer 78, the circuit board 68, and the portion of the plurality of terminal pins 70. That is, the second material layer 83 may encase the entirety of the circuit board 68 and the first material layer 78 and encloses portions of the plurality of terminal pins 70 while circumferentially surrounding but spaced apart from the terminating end 76a within the cavity 88. As such, the second material layer 83 forms and/or defines the connector interface portion 84 of the connector assembly 15 and forms the plurality of latch members 52 to removably couple the connector assembly 15 to the housing 12. The second material layer 83 may be different from the first material layer 78.

The above-described example pedal assembly provides a connector assembly that includes multi-layers of different types of overmold materials. A circuit board of the connector assembly is partially coated or encased with a first layer of a low-pressure epoxy overmold. A second layer is positioned to circumferentially cover portions of the first layer, the circuit board, and from the interface. The connector assembly may be easily removed, replaced, and the like, without the need to repair or replace the pedal assembly, which is required in conventional assemblies. As such, the connector assembly described herein provides versatility in that it may be easily replaced, may be configured to releasably couple floor mounted or hanging pedal assembly, and provides improved protection to the circuit board and electrical components thereof.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. An assembly comprising:
a circuit board having a plurality of electrical components;
a plurality of terminal pins extending from the circuit board;
a first material layer encases a portion of the circuit board and the plurality of electrical components; and
a second material layer encloses the first material layer and the circuit board, the second material layer defines a connector interface portion having a plurality of latch members extending therefrom.

2. The assembly of claim 1, wherein a material of the second material layer different from a material of the first material layer.

3. The assembly of claim 2, wherein:
the material of the first material layer is a low pressure epoxy; and
the material of the second material layer is a thermoplastic material.

4. The assembly of claim 1, wherein the second material layer encases the entire circuit board.

5. The assembly of claim 1, wherein the connector interface portion further comprises:
a connector having a cavity to provide access to the plurality of terminal pins extending from the circuit board.

6. The assembly of claim 1, further comprising:
a housing having a plurality of tabs extending therefrom that correspond to the plurality of latch members.

7. The assembly of claim 6, wherein each of the plurality of latch members are resilient members with a U-shaped latch and an opening configured to receive a respective tab from the plurality of tabs of the housing.

8. The assembly of claim 7, wherein when each opening of the plurality of latch members receive the respective tab from the plurality of tabs of the housing, the connector interface portion is releasably coupled to the housing in a snap-fit arrangement.

9. A pedal assembly comprising:
a housing having a plurality of tabs extending therefrom;
a pedal arm configured to move relative to the housing;
a connector assembly releasably coupled to the housing, the connector assembly including:
a circuit board having:
a first end, an opposite second end, and a surface extending between the first end and the second end, and
a plurality of electrical components coupled to the surface adjacent to the first end;
a plurality of terminal pins extending from the first end of the circuit board;
a first material layer encases the first end, the plurality of electrical components, and a portion of the plurality of terminal pins; and
a second material layer encloses the first material layer and the circuit board, the second material layer defines a connector interface portion and a plurality of latch members, each of the plurality of latch members include an opening that is configured to receive a respective tab from the plurality of tabs of the housing to releasably couple the connector assembly to the housing.

10. The pedal assembly of claim 9, wherein a material of the second material layer is different from a material of the first material layer.

11. The pedal assembly of claim 9, wherein the connector assembly further comprises:
a peripheral edge; and
a continuous wall extending from the peripheral edge, the continuous wall configured to abut a portion of the pedal arm when the pedal arm is in a fully depressed position.

12. The pedal assembly of claim 9, wherein the connector interface portion further comprises:
a connector having a cavity to provide access to a portion of the plurality of terminal pins extending from the circuit board.

13. The pedal assembly of claim 9, wherein the pedal assembly further comprises:
a sensor assembly comprising:
a coupler configured to move based on a movement of the pedal arm; and
the circuit board having:
a transmitting coil communicatively coupled to at least one of the plurality of electrical components; and
at least one receiver coil communicatively coupled to at least one of the plurality of electrical components, the at least one receiver coil positioned to sense a change in eddy currents caused from the movement of the coupler,
wherein the movement of the coupler is detected by the sensor assembly.

14. The pedal assembly of claim 13, wherein the connector interface portion further comprises:
an exterior surface;
an interior surface opposite of the exterior surface to define a thickness;
a recess portion positioned to extend in the interior surface; and
a perimeter wall that circumferentially surrounds the recess portion,
wherein the recess portion, the coupler, the transmitting coil and the at least one receiver coil are positioned to be coaxially aligned.

15. An assembly comprising:
a housing having a plurality of tabs extending therefrom;
a connector assembly releasably coupled to the housing, the connector assembly including:
a circuit board;
a plurality of terminal pins extending from the circuit board;
a first material layer encases a portion of the circuit board and a portion of the plurality of terminal pins; and
a second material layer encloses the first material layer and the circuit board, the second material layer defines a connector interface portion and a plurality of latch members, each of the plurality of latch members include an opening that is configured to receive a respective tab from the plurality of tabs of the housing to releasably couple the connector assembly to the housing.

16. The assembly of claim 15, further comprising:
a sensor assembly having:
a coupler; and
the circuit board having:
a transmitting coil; and
at least one receiver coil positioned to sense a change in eddy currents caused from a movement of the coupler,
wherein the movement of the coupler is detected by the sensor assembly.

17. The assembly of claim 16, wherein the connector interface portion further comprises:
an exterior surface;
an interior surface opposite of the exterior surface to define a thickness;
a recess portion positioned to extend in the interior surface; and
a perimeter wall that circumferentially surrounds the recess portion,
wherein the recess portion, the coupler, the transmitting coil and the at least one receiver coil are positioned to be coaxially aligned.

18. The assembly of claim 15, wherein a material of the second material layer is different from a material of the first material layer.

19. The assembly of claim 15, wherein the connector interface portion further comprises:
a connector having a cavity to provide access to a portion of the plurality of terminal pins extending from the circuit board.

20. The assembly of claim 15, wherein each of the plurality of latch members are resilient members with a U-shaped latch and the opening.
